(19) United States
(12) Patent Application Publication
(10) Pub. No.: US 2025/0286527 A1
(43) Pub. Date: Sep. 11, 2025

(54) DIELECTRIC FILTER

(71) Applicant: Murata Manufacturing Co., Ltd., Nagaokakyo-shi (JP)

(72) Inventor: Masashi ARAI, Nagaokakyo-shi (JP)

(21) Appl. No.: 19/220,780

(22) Filed: May 28, 2025

Related U.S. Application Data
(63) Continuation of application No. PCT/JP2023/030889, filed on Aug. 28, 2023.

(30) Foreign Application Priority Data
Nov. 28, 2022 (JP) 2022-189257

(51) Int. Cl. H03H 1/00; H01P 7/10

(52) U.S. Cl. CPC H03H 1/0007; H01P 7/10; H03H 2001/0085

(57) ABSTRACT

A filtering device includes a multilayer body and a plurality of resonators. The multilayer body includes a plurality of dielectric layers and has a rectangular parallelepiped shape. Each of the plurality of resonators is located inside the multilayer body and extends in a first direction orthogonal to a stacking direction of the multilayer body. The multilayer body includes lateral surfaces in a direction orthogonal to the first direction, and includes a region where the plurality of resonators are arranged and regions where the plurality of resonators are not arranged. The first and second lateral surfaces in the former region extend to a greater extent in the first direction than the first and second lateral surfaces in the latter regions.

### CROSS REFERENCE TO RELATED APPLICATION

This is a continuation of International Application No. PCT/JP2023/030889 filed on Aug. 28, 2023 which claims priority from Japanese Patent Application No. 2022-189257 filed on Nov. 28, 2022. The contents of these applications are incorporated herein by reference in their entireties.

### BACKGROUND OF THE DISCLOSURE

### Field of the Disclosure

The present disclosure relates to dielectric filters, and more specifically relates to a technique for preventing structural defects in a process of manufacturing a dielectric filter.

### Description of the Related Art

Japanese Patent Laid-Open No. 2007-235465 discloses a bandpass filter with a multilayer dielectric resonator in which a plurality of internal electrode layers are stacked together inside a dielectric body. In the bandpass filter disclosed in Japanese Patent Laid-Open No. 2007-235465, an inductor portion of the internal electrode layer is formed in a longitudinal pattern, and shaped in such a manner that a part of the longitudinal pattern has a tapering width. Such a structural feature makes it possible to lower the resonance frequency without reducing the Q-factor, and accordingly, the resonator can be downsized.

### BRIEF SUMMARY OF THE DISCLOSURE

The dielectric filter as disclosed in Japanese Patent Laid-Open No. 2007-235465 is used, for example, for filtering radio frequency signals for a small-sized mobile terminal which is typically a mobile phone or a smart phone.

Some dielectric filters are manufactured by stacking together a plurality of dielectric layers with plate conductors disposed thereon, and compression-bonding or sintering them. In a process of manufacturing such a multilayer dielectric filter, if the conductor density in the stacking direction is partially larger, a difference in thermal expansion coefficient between the portion where the conductor density is larger and a portion where the conductor density is smaller may cause structural defects including a crack between the conductor and the dielectric, and deformation of the internal structure such as bending or dimensional change of the conductor. Such structural defects may lead to device breakage or deterioration of the filtering characteristics.

The present disclosure is made to solve such problems, and an object of the present disclosure is to prevent structural defects in a process of manufacturing a dielectric filter.

A dielectric filter according to the present disclosure includes a multilayer body and a plurality of resonators. The multilayer body includes a plurality of dielectric layers and has a substantially rectangular parallelepiped shape. The plurality of resonators are located inside the multilayer body and extend in a first direction orthogonal to a stacking direction of the multilayer body. The multilayer body includes a first lateral surface and a second lateral surface in a direction orthogonal to the first direction, and includes a first region where the plurality of resonators are arranged and second regions where the plurality of resonators are not arranged. The first lateral surface and the second lateral surface in the first region extend to a greater extent in the first direction than the first lateral surface and the second lateral surface in the second regions.

The dielectric filter according to the present disclosure has the feature: the multilayer body defining the outer shape of the filter has the lateral surfaces that extend to a greater extent in the first region where the conductors of the resonators are arranged, than the lateral surfaces in the second regions where the conductors are not arranged. In a process of manufacturing the filter, such a feature enables reduction of stress between the first region and the second region caused by shrinkage of the dielectric layers in the second region, to thereby enable prevention of structural defects of the dielectric filter.

### BRIEF DESCRIPTION OF THE SEVERAL VIEWS OF THE DRAWINGS

FIG. 1 is a block diagram of a communication apparatus including a radio frequency front-end circuit to which a filtering device according to Embodiment 1 is applicable.

FIG. 2 is an external perspective view of the filtering device according to Embodiment 1.

FIG. 3 is a transparent perspective view illustrating an internal structure of the filtering device according to Embodiment 1.

FIG. 4 is a side transparent view of the filtering device according to Embodiment 1, as seen in the positive direction of an X axis.

FIG. 5 is a side view of a filtering device according to Embodiment 2, as seen in the positive direction of a Y axis.

FIG. 6 is a cross-sectional view of the filtering device along line VI-VI in FIG. 5.

FIG. 7 is a side view of a filtering device according to Embodiment 3, as seen in the positive direction of the Y axis.

FIG. 8 is a cross-sectional view of the filtering device along line VIII-VIII in FIG. 7.

FIG. 9 is a cross-sectional view of the filtering device along line IX-IX in FIG. 7.

FIG. 10 is a side view of a filtering device according to Embodiment 4, as seen in the positive direction of the Y axis.

FIG. 11 is a cross-sectional view of the filtering device along line XI-XI in FIG. 10.

FIG. 12 is a cross-sectional view of the filtering device along line XII-XII in FIG. 10.

FIG. 13 is a side view of a filtering device according to Embodiment 5, as seen in the positive direction of the Y axis.

FIG. 14 is a cross-sectional view of the filtering device along line XIV-XIV in FIG. 13.

### DETAILED DESCRIPTION OF THE DISCLOSURE

Embodiments of the present disclosure are hereinafter described in detail with reference to the drawings. In the drawings, the same or corresponding parts are denoted by the same reference characters, and a description thereof is not herein repeated.

### Embodiment 1

### (Basic Configuration of Communication Apparatus)

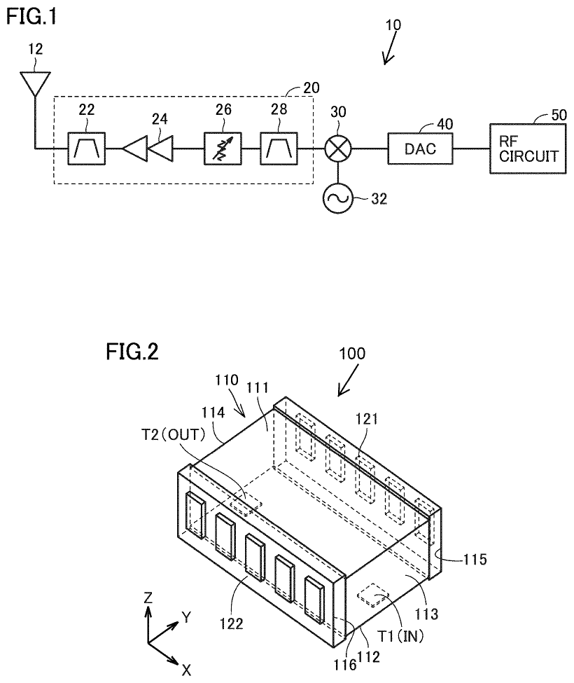

FIG. 1 is a block diagram of a communication apparatus 10 including a radio frequency front-end circuit 20 to which a filtering device 100 of Embodiment 1 is applicable. Examples of communication apparatus 10 may include, for example, mobile terminals, typically smartphones, and base stations for mobile phones.

With reference to FIG. 1, communication apparatus 10 includes an antenna 12, a radio frequency front-end circuit 20, a mixer 30, a local oscillator 32, a D/A converter (DAC) 40, and an RF circuit 50. Radio frequency front-end circuit 20 includes bandpass filters 22 and 28, an amplifier 24, and an attenuator 26. In the following description referring to FIG. 1, radio frequency front-end circuit 20 includes a transmission circuit that transmits radio frequency signals from antenna 12, however, radio frequency front-end circuit 20 may also include a reception circuit that receives radio frequency signals through antenna 12.

Communication apparatus 10 up-converts a signal transmitted from RF circuit 50 into a radio frequency signal and outputs the radio frequency signal from antenna 12. A modulated digital signal output from RF circuit 50 is converted by D/A converter 40 into an analog signal. Mixer 30 mixes the analog signal generated by D/A converter 40 with an oscillation signal from local oscillator 32 to up-convert the resulting signal into a radio frequency signal. Bandpass filter 28 removes any unwanted wave generated by the up-conversion and extracts only the signal within a desired frequency band. Attenuator 26 adjusts the intensity of the signal. Amplifier 24 amplifies the signal having passed through attenuator 26 to a predetermined power level. Bandpass filter 22 removes any unwanted wave generated during the amplification and passes only signal components within a frequency band specified by the communication standards. The signal having passed through bandpass filter 22 is emitted from antenna 12 as a transmission signal.

The filtering device as disclosed herein may be used as bandpass filters 22, 28 of communication apparatus 10 as described above.

### (Configuration of Filtering Device)

A configuration of a filtering device 100 according to Embodiment 1 is hereinafter described in detail with reference to FIGS. 2 to 4. Filtering device 100 is a dielectric filter including a plurality of resonators, each of which defines and functions as a distributed parameter element.

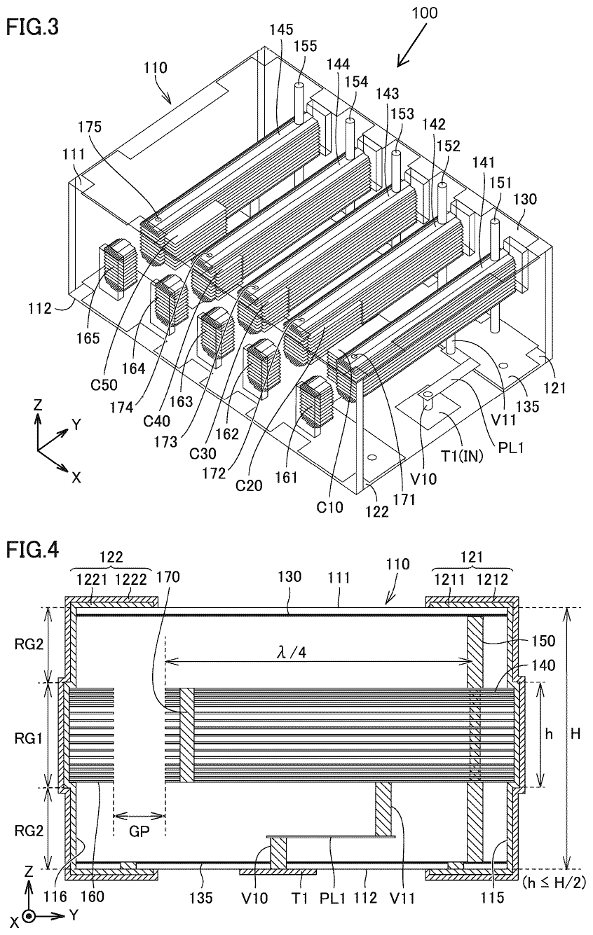

FIG. 2 is an external perspective view of filtering device 100. FIG. 2 shows only structural features of filtering device 100 that are visible from its outer surface side, and does not show its internal structural features. FIG. 3 is a transparent perspective view illustrating an internal structure of filtering device 100. FIG. 4 is a side transparent view of filtering device 100.

With reference to FIG. 2, filtering device 100 includes a substantially rectangular parallelepiped multilayer body 110 in which a plurality of dielectric layers are stacked together in the stacking direction. In the description below, “Z-axis direction” refers to the stacking direction of multilayer body 110, “X-axis direction” refers to the direction along the longer sides of multilayer body 110 and perpendicular to the Z-axis direction, and “Y-axis direction” (first direction) refers to the direction along the shorter sides of multilayer body 110. In the description below, the upper side and the lower side may respectively refer to the positive direction of the Z axis and the negative direction of the Z axis in the drawings.

Multilayer body 110 has an upper surface 111, a lower surface 112, a lateral surface 113, a lateral surface 114, a lateral surface 115, and a lateral surface 116. Lateral surface 113 is a lateral surface of multilayer body 110 in the positive direction of the X axis, while lateral surface 114 is a lateral surface in the negative direction of the X axis. Lateral surfaces 115 and 116 are lateral surfaces of multilayer body 110 that are perpendicular to the Y-axis direction.

The dielectric layers of multilayer body 110 are each made of resin or ceramic such as low temperature co-fired ceramics (LTCC), for example. In multilayer body 110, a plurality of plate conductors formed on respective dielectric layers and a plurality of vias formed between the dielectric layers provide the distributed parameter elements defining the resonators as well as capacitors and inductors to couple the distributed parameter elements. The “via” herein refers to a conductor that connects the respective conductors provided on different dielectric layers, and extends in the stacking direction. The via is formed of an electrically conductive paste, a plating, and/or a metallic pin, for example.

As illustrated in FIG. 2, filtering device 100 includes shield conductors 121 and 122 that cover lateral surfaces 115 and 116, respectively, of multilayer body 110. Shield conductors 121 and 122 each also cover a part of upper surface 111 and a part of lower surface 112 of multilayer body 110. As described in detail with reference to FIGS. 3 and 4, lateral surfaces 115 and 116 of multilayer body 110 partially protrude in the Y-axis direction and accordingly shield conductors 121 and 122 also partially protrude in the Y-axis direction.

Respective portions of shield conductors 121 and 122 that are located on lower surface 112 of multilayer body 110 are connected, with connecting conductors such as solder bumps, to ground electrodes on a mounting substrate, which is not shown. Thus, shield conductors 121 and 122 also function as ground terminals.

Filtering device 100 also includes an input terminal T1 and an output terminal T2 on lower surface 112 of multilayer body 110. Input terminal T1 on lower surface 112 is located relatively closer to lateral surface 113 in the positive direction of the X axis. Output terminal T2 on lower surface 112 is located relatively closer to lateral surface 114 in the negative direction of the X axis. Input terminal T1 and output terminal T2 are connected, with connecting conductors such as solder bumps, to respective electrodes on the mounting substrate.

Next, with reference to FIGS. 3 and 4, the internal structure of filtering device 100 is described. Filtering device 100 includes, in addition to the structural features illustrated in FIG. 2, plate electrodes 130 and 135, a plurality of resonators 141 to 145, capacitor electrodes 161 to 165, and connecting conductors 151 to 155 and 171 to 175. In the following description, resonators 141 to 145, capacitor electrodes 161 to 165, and connecting conductors 151 to 155 and 171 to 175 may be referred to collectively as “resonator 140,” “capacitor electrode 160,” “connecting conductor 150,” and “connecting conductor 170,” respectively.

Plate electrodes 130 and 135 are arranged inside multilayer body 110 and located at respective positions spaced from each other and facing each other in the stacking direction (Z-axis direction). Plate electrode 130 is disposed on a dielectric layer close to upper surface 111, and is connected to shield conductors 121 and 122 at respective ends along the X axis. As seen in a plan view in the stacking direction, plate electrode 130 has a shape that substantially covers the dielectric layers.

Plate electrode 135 is disposed on a dielectric layer close to lower surface 112 of multilayer body 110. As seen in a plan view in the stacking direction, plate electrode 135 has a substantially H shape with cutouts formed in respective portions facing input terminal T1 and output terminal T2. Plate electrode 135 is connected to shield conductors 121 and 122 at respective ends along the X axis.

In multilayer body 110, resonators 141 to 145 are arranged between plate electrode 130 and plate electrode 135. In filtering device 100, resonators 141 to 145 are located inside multilayer body 110 and arranged in the X-axis direction. More specifically, resonators 141, 142, 143, 144, and 155 are arranged in this order from the positive direction toward the negative direction of the X axis.

Resonators 141 to 145 each extend in the Y-axis direction (first direction). Respective ends (first ends) of resonators 141 to 145 in the positive direction of the Y axis are connected to shield conductor 121. Respective ends (second ends) of resonators 141 to 145 in the negative direction of the Y axis are spaced from shield conductor 122.

Resonators 141 to 145 each include a plurality of conductors arranged in the stacking direction. The number of conductors defining each resonator is 13 or more, for example. In resonator 140, a plurality of conductors defining each resonator are electrically connected together by connecting conductor 170, at a position close to the second end on the shield conductor 122 side. Resonators 141 to 145 are connected to plate electrodes 130 and 135 through respective connecting conductors 151 to 155, at respective positions close to the first end connected to shield conductor 121. Each of connecting conductors 151 to 155 extends from plate electrode 130 to plate electrode 135 through a plurality of conductors of a respective one of the resonators. Each of connecting conductors 151 to 155 is electrically connected to a plurality of conductors defining a respective one of the resonators.

In such a configuration, most of electric current flowing through each resonator flows to ground terminals (i.e., plate electrodes 130 and 135 and shield conductor 121) through a respective one of connecting conductors 151 to 155. Therefore, the effective length of each resonator is the length from the second end to this connecting conductor. Each resonator is designed to have a length of λ/4 (FIG. 4) from the second end to the connecting conductor (151 to 155). Resonator 140 functions as a distributed parameter TEM-mode resonator including a plurality of conductors as center conductors and plate electrodes 130 and 135 as outer conductors.

Resonator 141 is connected to input terminal T1 through vias V10 and V11 and a plate electrode PL1. Resonator 145 is connected to output terminal T2 through vias and a plate electrode PL2, which is not seen in FIG. 3 because they are hidden behind the resonator. Resonators 141 to 145 are magnetically coupled to one another, and a radio frequency signal input to input terminal T1 is transmitted by resonators 141 to 145 in this order and output from output terminal T2. At this time, filtering device 100 functions as a bandpass filter, using the degree of coupling between the resonators.

The second-end side of each resonator 140 is provided with a respective one of capacitor electrodes C10 to C50 protruding towards an adjacent resonator. Some of a plurality of conductors of the resonator protrude outward to form the capacitor electrode. The degree of capacitive coupling between the resonators is adjustable by the length of the capacitor electrode in the Y-axis direction, the distance from the capacitor electrode to the adjacent resonator, and/or the number of conductors defining the capacitor electrode.

In filtering device 100, capacitor electrode C10 protrudes from resonator 141 toward resonator 142, and capacitor electrode C20 protrudes from resonator 142 toward resonator 141, as illustrated in FIG. 3. Moreover, capacitor electrode C30 protrudes from resonator 143 toward resonator 142, and capacitor electrode C40 protrudes from resonator 144 toward resonator 143. Further, capacitor electrode C50 protrudes from resonator 145 toward resonator 144.

Capacitor electrodes C10 to C50 are not indispensable features and, as long as a desired degree of inter-resonator coupling is achievable, some or all of the capacitor electrodes may not be provided. In addition to the features illustrated in FIG. 3, the filtering device may further include a capacitor electrode protruding from resonator 142 toward resonator 143, a capacitor electrode protruding from resonator 143 toward resonator 144, and a capacitor electrode protruding from resonator 144 toward resonator 145.

In addition, in filtering device 100, capacitor electrodes 160 are arranged, facing the second ends of resonators 140, respectively. The shape of each capacitor electrode 160 in a cross section parallel to a Z-X plane is similar to that of resonator 140. Capacitor electrodes 160 are connected to shield conductor 122. Thus, each resonator 140 and a respective one of capacitor electrodes 160 define a capacitor. The capacitance value of the capacitor defined by resonator 140 and respective capacitor electrode 160 is adjustable by adjusting a gap GP (distance in the Y-axis direction) between resonator 140 and capacitor electrode 160 illustrated in FIG. 4.

As described above with reference to FIG. 2, filtering device 100 of Embodiment 1 has lateral surfaces 115 and 116 of multilayer body 110 that partially protrude outward. More specifically, as illustrated in FIG. 4, lateral surfaces 115 and 116 of multilayer body 110 extend to a greater extent in the Y-axis direction in a region RG1 where the conductors of resonator 140 and capacitor electrode 160 are arranged, than lateral surfaces 115 and 116 in a region RG2 where the conductors of resonator 140 and capacitor electrode 160 are not arranged. In one example, region RG1 is designed to have a dimension h in the stacking direction that is one-half or less of a dimension H in the stacking direction of multilayer body 110 (h≤H/2). Region R2 may include not only the region extending from region RG1 toward upper surface 131 and the region extending from region RG1 toward lower surface 132, but also a region between the resonators and a region between the capacitor electrodes, and respective regions from the opposite endmost resonators to lateral surfaces 113 and 114 and respective regions from the opposite endmost capacitor electrodes to lateral surfaces 113 and 114.

In filtering device 100 of Embodiment 1, each of shield conductors 121 and 122 has a double-layer structure formed by different electrical conductors. Specifically, shield conductor 121 includes two electrode layers 1211 and 1212, and shield conductor 122 includes two electrode layers 1221 and 1222.

Electrode layers 1211 and 1221 are formed by applying or printing, on the surface of multilayer body 110, an electrically conductive paste containing copper (Cu), nickel (Ni), silver (Ag), or the like, and firing the paste to thereby solidify the paste. In the following, an electrode layer formed by such printing or the like is also referred to as “underlying electrode.” Electrode layers 1212 and 1222 are formed by performing sputtering or plating of nickel, tin (Sn), or Ni—Sn alloy on electrode layers 1211 and 1221 serving as underlying electrodes. Electrode layers 1211 and 1221 are greater in thickness than electrode layers 1212 and 1222.

Shield conductors 121 and 122 each cover a part of upper surface 111 and a part of lower surface 112, and cover lateral surfaces 115 and 116, respectively. Accordingly, shield conductors 121 and 122 in regions RG1 of lateral surfaces 115 and 116 protrude outward relative to shield conductors 121 and 122 in regions RG2.

The multilayer dielectric filter as described above is generally manufactured by stacking together a plurality of dielectric layers with plate conductors disposed thereon, and compression-bonding or sintering them. The shrinkage of the dielectric such as ceramic is larger than the shrinkage of the conductor, and therefore, in a process of manufacturing the dielectric filter, if there are dielectric layers with a high conductor density in the stacking direction like region RG1, and dielectric layers with a low conductor density like region RG2, a difference in thermal expansion coefficient between these two regions causes stress applied to the conductor in the direction of compression, at the interface between the conductor and the dielectric. As a result, structural defects may occur between the conductor and the dielectric, such as a crack, separation between dielectric layers, deformation due to buckling of the conductor, and/or deterioration of the flatness of the surface of the multilayer body. Occurrence of such structural defects may cause reduction of the strength of the filtering device, or shortening of the device life. Further, there is a possibility that a capacitance value and an inductance value intended by design cannot be implemented, resulting in deterioration of the filtering characteristics.

Filtering device 100 of Embodiment 1 has the feature: dielectric layers of region RG1 where conductors of multilayer body 110 are arranged protrude relative to dielectric layers of region RG2 where the conductors are not arranged. Such a feature can be achieved by adjusting the temperature increase profile in the firing step and making the timing at which the dielectric (ceramic) in region RG2 shrinks different from the timing at which the conductor in region RG1 shrinks. Such adjustment of the shrinkage timing reduces the stress generated at the interface between the dielectric and the conductor, so that occurrence of structural defects such as crack can be prevented in the process of manufacturing filtering device 100. Accordingly, breakage, for example, of filtering device 100 can be prevented, and deterioration of the filtering characteristics can be suppressed.

Region RG2 that is sufficiently larger than region RG1 makes it easier to alleviate the stress occurring to the conductor during shrinkage in region RG1. It is therefore preferable to set dimension h of region RG1 in the stacking direction to one-half or less of dimension H of multilayer body 110 in the stacking direction.

Moreover, shield conductors 121 and 122 can have steps formed so as to conform to the protrusion. Such a structure can prevent the solder from extending toward upper surface 111, when filtering device 100 is mounted on a substrate by soldering.

“Lateral surface 115” and “lateral surface 116” in Embodiment 1 correspond to “first lateral surface” and “second lateral surface” in the present disclosure, respectively. “Region RG1” and “region RG2” in Embodiment 1 correspond to “first region” and “second region” in the present disclosure, respectively. “Plate electrode 130” and “plate electrode 135” in Embodiment 1 correspond to “first plate electrode” and “second plate electrode” in the present disclosure, respectively. “Shield conductor 121” and “Shield conductor 122” in Embodiment 1 correspond to “first shield conductor” and “second shield conductor” in the present disclosure, respectively. Each of “connecting conductors 151 to 155” in Embodiment 1 corresponds to “first connecting conductor” in the present disclosure. Each of “connecting conductors 171 to 175” in Embodiment 1 corresponds to “second connecting conductor” in the present disclosure.

### Embodiment 2

In connection with Embodiment 2, another configuration of the shield conductors formed on lateral surfaces 115 and 116 of multilayer body 110 is described.

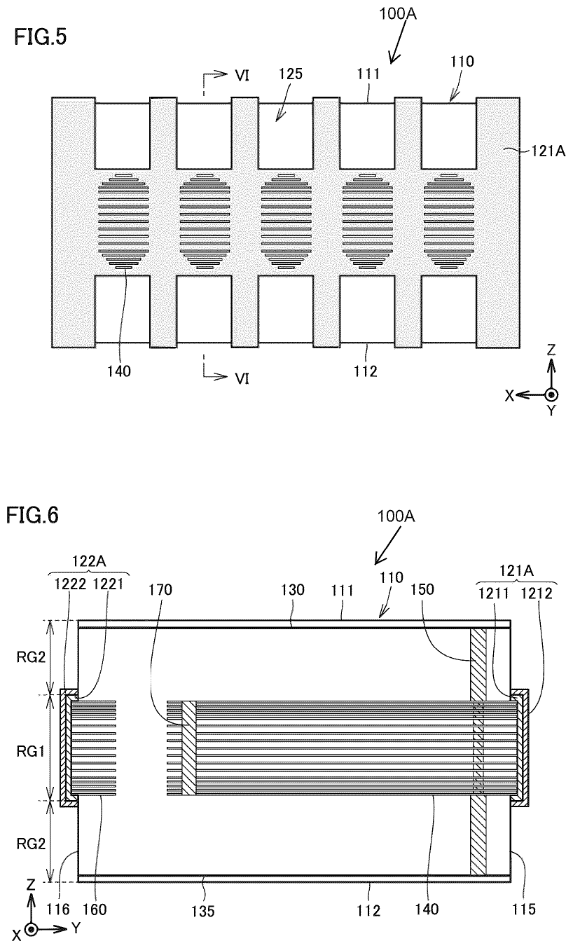

FIG. 5 is a side view of a filtering device 100A according to Embodiment 2, as seen in the positive direction of the Y axis. FIG. 6 is a cross-sectional view of filtering device 100A along line VI-VI in FIG. 5.

Shield conductors 121 and 122 of filtering device 100 in Embodiment 1 are disposed to cover the whole of lateral surface 115 and the whole of lateral surface 116, respectively. In contrast, as illustrated in FIG. 5, in the portion where resonator 140 is formed, a shield conductor 121A disposed on lateral surface 115 of filtering device 100A in Embodiment 2 has a cutout 125 formed in each of respective regions RG2 on the upper side and the lower side of resonator 140. Thus, in these regions, lateral surface 115 of multilayer body 110 is exposed.

As illustrated in FIG. 6, in the cross section of the portion where cutouts 125 are formed, shield conductors 121A and 122A are disposed on only respective ends of resonator 140 and capacitor electrode 160. In contrast, in the portion between adjacent resonators and respective portions between the endmost resonators and lateral surfaces 113 and 114, shield conductors 121A and 122A are disposed from upper surface 111 through lateral surface 115, 116 to lower surface 112. The shield conductor located in the portions where the resonator is not disposed ensures connection with plate electrodes 130 and 135 in multilayer body 110.

If, like filtering device 100, the firing step is performed in the state where the whole of lateral surfaces 115 and 116 is covered with electrode layers 1211 and 1221 which are underlying electrodes of shield conductors 121 and 122, the dielectric restrained by electrode layers 1211 and 1221 may cause the cross section of the multilayer body to be deformed into a drum shape. As a result, tensile stress in the stacking direction may be applied to the dielectric layers, to cause separation between dielectric layers and/or separation between the dielectric and the conductor. Like filtering device 100A of Embodiment 2, in the portion of lateral surface 115 where resonator 140 is disposed, cutouts 125 formed on the upper side and the lower side of resonator 140 alleviate restriction of region RG2 caused by the shield conductors. Thus, it is possible to reduce occurrence of stress in the stacking direction and prevent structural defects due to separation between the dielectric and the conductor.

Moreover, the difference in shield conductor shrinkage between region RG1 and region RG2 is eliminated, and therefore, it is also possible to reduce nonlinear distortion of the end of the conductor due to the difference in shield conductor shrinkage.

### Embodiment 3

In connection with Embodiment 3, a configuration is described where the shield conductor in region RG1 with conductors is formed by sputtering or plating only, without using the underlying electrode.

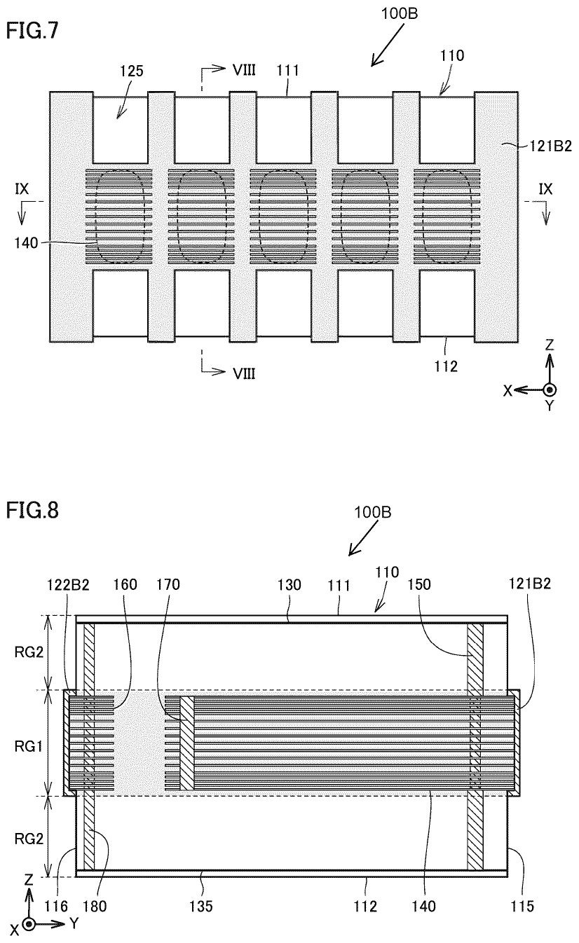

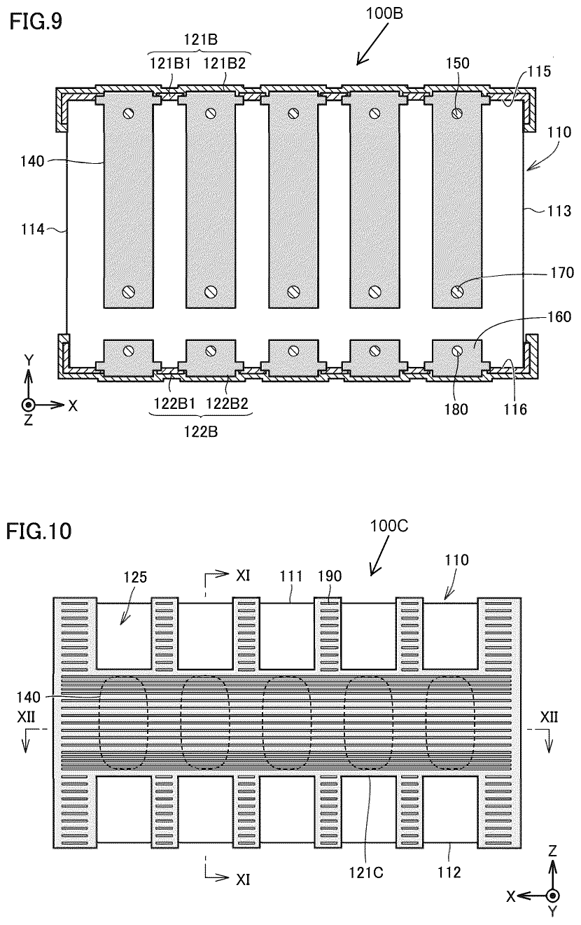

FIG. 7 is a side view of a filtering device 100B according to Embodiment 3, as seen in the positive direction of the Y axis. FIG. 8 is a cross-sectional view of filtering device 100B along line VIII-VIII of FIG. 7. FIG. 9 is a cross-sectional view of filtering device 100B along line IX-IX in FIG. 7.

With reference to FIGS. 7 to 9, like filtering device 100A of Embodiment 2, filtering device 100B according to Embodiment 3 has cutouts 125 formed in shield conductors 121B and 122B and located on the upper side and the lower side of resonator 140 and capacitor electrode 160. However, as illustrated in FIGS. 8 and 9, electrode layers 121B1 and 122B1 of the underlying electrodes are not disposed on respective ends of the conductors of resonator 140 and capacitor electrode 160 in region RG1, and only electrode layers 121B2 and 122B2 formed by sputtering or plating are disposed. Namely, electrode layers 121B1 and 122B1 are disposed between adjacent resonators 140, between adjacent capacitor electrodes 160, and respective portions where lateral surfaces 115 and 116 are contiguous to lateral surfaces 113 and 114.

As described above, when electrode layers 121B1 and 122B1 serving as underlying electrodes are applied and fired, stress is generated due to restraint of the dielectric layers by electrode layers 121B1 and 122B1. Therefore, the underlying electrodes are not provided in the region where the conductors of resonator 140 and capacitor electrode 160 are disposed, to thereby enable reduction of the stress in this region during the firing step. Thus, the stress acting on the dielectric and the conductor can be suppressed, so that occurrence of structural defects in the process of manufacturing can be prevented.

In filtering device 100B, glass containing a metal component (e.g., copper) that easily diffuses in the firing step is added to the dielectric in the portion (region RG1) where the conductors of resonator 140 and capacitor electrode 160 are disposed. Thus, the concentration of copper contained in the dielectric layers can be made higher than that in region RG2, to improve the adhesion of the metal member adhered by sputtering and plating.

In addition, in filtering device 100B as illustrated in FIG. 9, the end of the conductor of resonator 140 in lateral surface 115 and the end of the conductor of capacitor electrode 160 in lateral surface 116 each have a larger conductor width than the conductor width of the other portions. The enlarged conductor portions are connected respectively to electrode layers 121B1 and 122B1 serving as underlying electrodes. This ensures electrical connection between the conductors of resonator 140 and capacitor electrode 160, and plate electrodes 130 and 135.

Further, each of capacitor electrodes 160 is provided with a connecting conductor 180 that connects the conductors of capacitor electrode 160 and plate electrodes 130 and 135. Thus, reliable electrical connection between capacitor electrode 160 and plate electrodes 130 and 135 can be achieved.

“Connecting conductor 180” in Embodiment 3 corresponds to “third connecting conductor” in the present disclosure.

### Embodiment 4

In Embodiment 3, only the shield conductors in the portions where the conductors of resonator 140 and capacitor electrode 160 are disposed are formed by sputtering or plating, and the shield conductors in the other portions have a double-layer structure in which underlying electrodes are used.

In connection with Embodiment 4, a configuration where shield conductors disposed on lateral surfaces 115 and 116 are entirely formed by sputtering or plating is described.

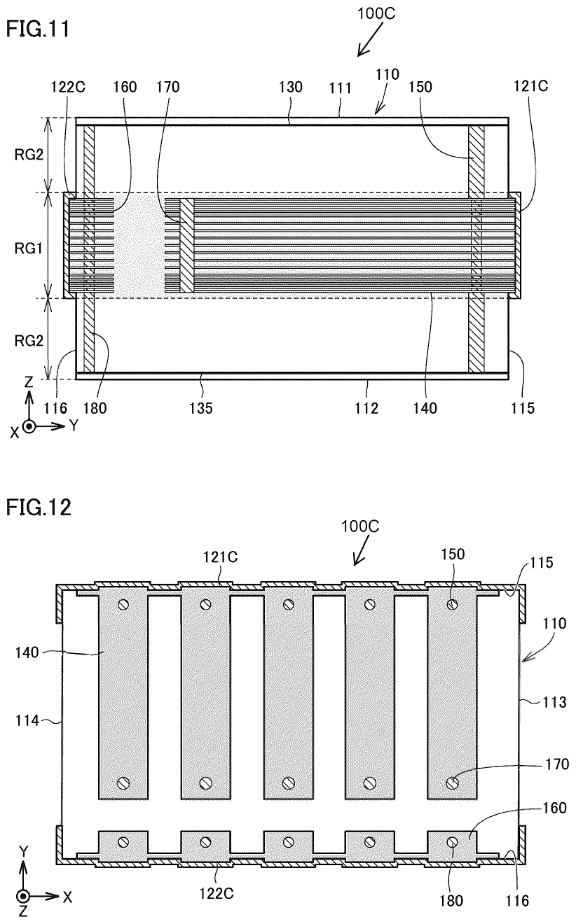

FIG. 10 is a side view of a filtering device 100C according to Embodiment 4, as seen in the positive direction of the Y axis. FIG. 11 is a cross-sectional view of filtering device 100C along line XI-XI in FIG. 10. FIG. 12 is a cross-sectional view of filtering device 100C along line XII-XII in FIG. 10.

Referring to FIGS. 10 to 12, shield conductors 121C and 122C of filtering device 100C in Embodiment 4 are basically shaped identically to those of filtering device 100A in Embodiment 2, and cutouts 125 are formed on the upper side and the lower side of resonator 140. However, as illustrated in FIGS. 11 and 12, shield conductors 121C and 122C are conductors having a single-layer structure formed by sputtering or plating. Thus, the shield conductors can be formed by only sputtering or plating without using underlying electrodes, to eliminate the restraint of the dielectric layers by the underlying electrodes in the firing step. It is therefore possible to suppress stress between the dielectric and the conductor, and prevent occurrence of structural defects in the process of manufacturing.

In the case where plating is performed, it is desirable to increase the electrical conductivity of the region where the shield conductor is to be formed. In view of this, in filtering device 100C as illustrated FIG. 12, resonators adjacent to each other and capacitor electrodes adjacent to each other are connected to each other in the proximity of the lateral surfaces. Further, in filtering device 100C, a plurality of plate electrodes 190 are stacked in the vicinity of lateral surfaces 115 and 116, in region RG2 where cutouts 125 are not formed. The ends of plate electrodes 190 are exposed to lateral surfaces 115 and 116. Thus, the electrical conductivity of lateral surfaces 115 and 116 in this region can be made substantially identical to that of the resonator portion, so that the adhesion of the metal member in the plating process can be enhanced.

Like Embodiment 3, in filtering device 100C, glass containing a metal component easily diffused in the firing step may be added to the dielectric layers in region RG1 and the dielectric layers in regions RG2 where plate electrodes 190 are disposed.

In this way, the shield conductors on the lateral surfaces of the multilayer body are formed by sputtering or plating without using underlying electrodes, to thereby enable reduction of the stress generated in the firing step, and prevention of occurrence of structural defects.

### Embodiment 5

In connection with Embodiment 5, a configuration is described where shield conductors formed by sputtering or plating are disposed from the upper surface to the lower surface, only on the portions of the lateral surfaces where the resonators and the capacitor electrodes are located.

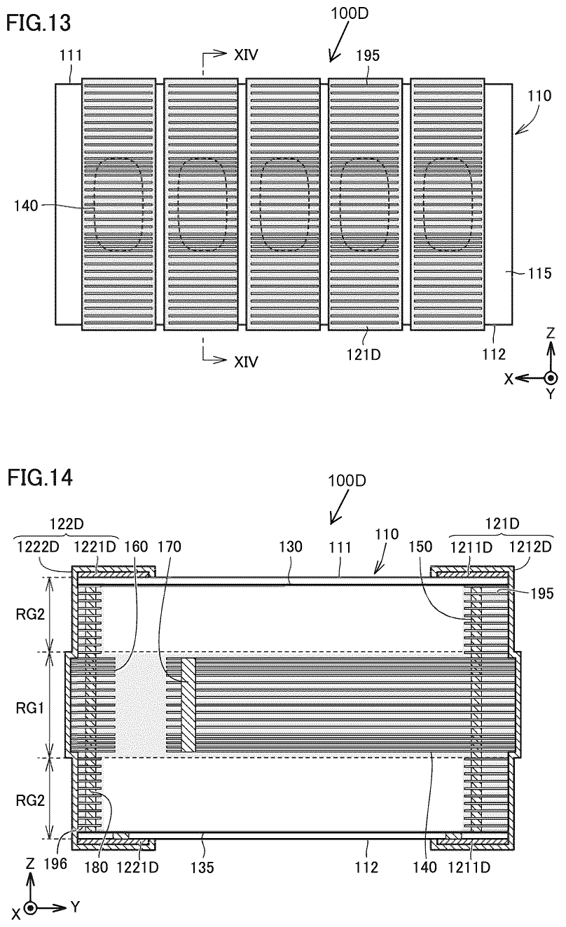

FIG. 13 is a side view of a filtering device 100D according to Embodiment 5, as seen in the positive direction of the Y axis. FIG. 14 is a cross-sectional view of filtering device 100D along line XIV-XIV in FIG. 13.

In filtering device 100D as illustrated in FIG. 13, a shield conductor 121D is disposed from upper surface 111 to lower surface 112 through lateral surface 115, only in the portions where resonators 140 are disposed. Namely, on lateral surface 115, the shield conductor is not disposed in the region between resonators adjacent to each other and the region close to each of lateral surfaces 113 and 114.

Shield conductor 121D in this region of the lateral surface is formed by sputtering or plating without using the underlying electrode. Therefore, a plurality of plate electrodes 195 are stacked in the vicinity of lateral surface 115, in regions RG2 on the upper side and the lower side of resonator 140 in multilayer body 110. This plate electrode 195 can enhance the adhesion of the metal member in the sputtering or plating process.

On lateral surface 116 as well, a shield conductor 122D is disposed to extend from upper surface 111 to lower surface 112 through lateral surface 116, only in the region where capacitor electrode 160 is disposed. A plurality of plate electrodes 196 are stacked in the vicinity of lateral surface 116, in regions RG2 on the upper side and the lower side of capacitor electrode 160 in multilayer body 110. This plate electrode 196 can enhance the adhesion of the metal member to lateral surface 116 in the sputtering or plating process.

Shield conductors 121D and 122D on upper surface 111 and lower surface 112 are formed in a double-layer structure made up of an electrode (underlying electrode) formed by a process such as printing and an electrode formed by sputtering or plating. Specifically, shield conductor 121D includes an electrode layer 1211D serving as the underlying electrode and an electrode layer 1212D formed by plating for example. Shield conductor 122D includes an electrode layer 1221D serving as the underlying electrode and an electrode layer 1222D formed by plating, for example.

On upper surface 111 and lower surface 112, it is necessary to ensure more reliable electrical connection between connecting conductor 150 for resonator 140 and shield conductor 121D, and electrical connection between connecting conductor 180 for capacitor electrode 160 and shield conductor 122D. In view of this, in filtering device 100D, the double-layer structure using the underlying electrode is adopted for shield conductors 121D and 122D on upper surface 111 and lower surface 112. Since the underlying electrode is disposed on only upper surface 111 and lower surface 112, stress due to the electrode between the dielectric and the conductor hardly occurs in the firing step.

Like Embodiment 3, in filtering device 100D, glass containing a metal component easily diffused in the firing step may be added to the dielectric layers in region RG1 and the dielectric layers in regions RG2 where plate electrodes 195 and 196 are disposed.

In this way, the shield conductors on the lateral surfaces of the multilayer body are formed by sputtering or plating without using underlying electrodes, to thereby enable reduction of the stress generated in the firing step, and prevention of occurrence of structural defects.

### (Aspects)

It should be understood by those skilled in the art that the foregoing embodiments are specific examples of the following aspects.

(Clause 1) A dielectric filter according to one aspect includes a multilayer body and a plurality of resonators. The multilayer body includes a plurality of dielectric layers and has a substantially rectangular parallelepiped shape. The plurality of resonators are located inside the multilayer body and extend in a first direction orthogonal to a stacking direction of the multilayer body. The multilayer body includes a first lateral surface and a second lateral surface in a direction orthogonal to the first direction, and includes a first region where the plurality of resonators are arranged and second regions where the plurality of resonators are not arranged. The first lateral surface and the second lateral surface in the first region extend to a greater extent in the first direction than the first lateral surface and the second lateral surface in the second regions.

(Clause 2) The dielectric filter according to Clause 1 further includes a first plate electrode and a second plate electrode, and a first shield conductor and a second shield conductor. The first plate electrode and the second plate electrode are located inside the multilayer body and spaced from each other in the stacking direction. The first shield conductor and a second shield conductor are arranged respectively on the first lateral surface and the second lateral surface of the multilayer body, and connected to the first plate electrode and the second plate electrode. The plurality of resonators are arranged between the first plate electrode and the second plate electrode. The plurality of resonators each have a first end connected to the first shield conductor and a second end spaced from the second shield conductor.

(Clause 3) In the dielectric filter according to Clause 2, in the first shield conductor, a cutout is formed in at least a part of each of the second regions that extend respectively toward the first plate electrode and the second plate electrode from the first region.

(Clause 4) In the dielectric filter according to Clause 2, each of the plurality of resonators includes a plurality of conductors extending in the first direction and stacked together in the stacking direction.

(Clause 5) The dielectric filter according to Clause 4 further includes a first connecting conductor disposed at the first end of each resonator of the plurality of resonators, connecting the resonator to the first plate electrode and the second plate electrode, and electrically connecting the plurality of conductors to each other.

(Clause 6) The dielectric filter according to Clause 4 or 5 further includes a second connecting conductor disposed at the second end of each resonator of the plurality of resonators, and electrically connecting the plurality of conductors to each other.

(Clause 7) The dielectric filter according to Clause 2 further includes a capacitor electrode facing the second end of each resonator of the plurality of resonators, and connected to the second shield conductor.

(Clause 8) In the dielectric filter according to Clause 7, in the second shield conductor, a cutout is formed in at least a part of each of the second regions that extend respectively toward the first plate electrode and the second plate electrode from the first region.

(Clause 9) In the dielectric filter according to Clause 7, the capacitor electrode includes a plurality of conductors extending in the first direction and stacked together in the stacking direction. The dielectric filter further includes a third connecting conductor connecting the capacitor electrode to the first plate electrode and the second plate electrode, and electrically connecting the plurality of conductors to each other.

(Clause 10) In the dielectric filter according to Clause 2, the first shield conductor and the second shield conductor are formed by applying a metal paste to the first lateral surface and the second lateral surface respectively and firing the metal paste.

(Clause 11) In the dielectric filter according to Clause 2, the first shield conductor and the second shield conductor are formed by performing sputtering or plating on the first lateral surface and the second lateral surface, respectively.

(Clause 12) In the dielectric filter according to Clause 11, a concentration of copper included in the dielectric layers in the first region is higher than a concentration of copper included in the dielectric layers in the second regions.

(Clause 13) In the dielectric filter according to Clause 2, the first shield conductor and the second shield conductor are formed by applying a metal paste to the first lateral surface and the second lateral surface respectively and firing the metal paste, and thereafter performing sputtering or plating.

(Clause 14) In the dielectric filter according to Clause 1, in the stacking direction, a dimension of the first region is one-half or less of a dimension of the multilayer body.

It should be construed that the embodiments disclosed herein are given by way of illustration in all respects, not by way of limitation. It is intended that the scope of the present disclosure is defined by claims, not by the above description of the embodiments, and encompasses all modifications and variations equivalent in meaning and scope to the claims.

10 communication apparatus; 12 antenna; 20 radio frequency front-end circuit; 22, 28 bandpass filter; 24 amplifier; 26 attenuator; 30 mixer; 32 local oscillator; 40 D/A converter; 50 RF circuit; 100, 100A-100D filtering device; 110 multilayer body; 111 upper surface; 112 lower surface; 113-116 lateral surface; 121, 121A-121D, 122, 122A-122D shield conductor; 125 cutout; 130, 135, 190, 195, 196, PL1, PL2 plate electrode; 140-145 resonator; 150-155, 170-175, 180 connecting conductor; 160, 161-165, C10-C50 capacitor electrode; 121B1, 121B2, 122B1, 122B2, 1211, 1212, 1221, 1222, 1211D, 1212D, 1221D, 1222D electrode layer; RG1, RG2 region; T1 input terminal; T2 output terminal; V10, V11 via.

1. A dielectric filter comprising:
a multilayer body including a plurality of dielectric layers and having a substantially rectangular parallelepiped shape; and
a plurality of resonators located inside the multilayer body and extending in a first direction orthogonal to a stacking direction of the multilayer body; wherein
the multilayer body includes a first lateral surface and a second lateral surface in a direction orthogonal to the first direction, and includes a first region where the plurality of resonators are arranged and second regions where the plurality of resonators are not arranged, and
the first lateral surface and the second lateral surface in the first region extend to a greater extent in the first direction than the first lateral surface and the second lateral surface in the second regions.

2. The dielectric filter according to claim 1, further comprising:
a first plate electrode and a second plate electrode located inside the multilayer body and spaced from each other in the stacking direction; and
a first shield conductor and a second shield conductor arranged respectively on the first lateral surface and the second lateral surface of the multilayer body, and connected to the first plate electrode and the second plate electrode, wherein
the plurality of resonators are arranged between the first plate electrode and the second plate electrode, and
the plurality of resonators each have a first end connected to the first shield conductor and a second end spaced from the second shield conductor.

3. The dielectric filter according to claim 2, wherein in the first shield conductor, a cutout is provided in at least a part of each of the second regions extending respectively toward the first plate electrode and the second plate electrode from the first region.

4. The dielectric filter according to claim 2, wherein each of the plurality of resonators includes a plurality of conductors extending in the first direction and stacked together in the stacking direction.

5. The dielectric filter according to claim 4, further comprising a first connecting conductor disposed at the first end of each resonator of the plurality of resonators, connecting the resonator to the first plate electrode and the second plate electrode, and electrically connecting the plurality of conductors to each other.

6. The dielectric filter according to claim 4, further comprising a second connecting conductor disposed at the second end of each resonator of the plurality of resonators, and electrically connecting the plurality of conductors to each other.

7. The dielectric filter according to claim 2, further comprising a capacitor electrode facing the second end of each resonator of the plurality of resonators and connected to the second shield conductor.

8. The dielectric filter according to claim 7, wherein in the second shield conductor, a cutout is provided in at least a part of each of the second regions extending respectively toward the first plate electrode and the second plate electrode from the first region.

9. The dielectric filter according to claim 7, wherein
the capacitor electrode includes a plurality of conductors extending in the first direction and stacked together in the stacking direction, and
the dielectric filter further comprises a third connecting conductor connecting the capacitor electrode to the first plate electrode and the second plate electrode and electrically connecting the plurality of conductors to each other.

10. The dielectric filter according to claim 2, wherein the first shield conductor and the second shield conductor are provided by applying a metal paste to the first lateral surface and the second lateral surface respectively and firing the metal paste.

11. The dielectric filter according to claim 2, wherein the first shield conductor and the second shield conductor are provided by performing sputtering or plating on the first lateral surface and the second lateral surface, respectively.

12. The dielectric filter according to claim 11, wherein a concentration of copper included in the dielectric layers in the first region is higher than a concentration of copper included in the dielectric layers in the second regions.

13. The dielectric filter according to claim 2, wherein the first shield conductor and the second shield conductor are provided by applying a metal paste to the first lateral surface and the second lateral surface respectively and firing the metal paste, and thereafter performing sputtering or plating.

14. The dielectric filter according to claim 1, wherein, in the stacking direction, a dimension of the first region is one-half or less of a dimension of the multilayer body.

15. The dielectric filter according to claim 5, further comprising a second connecting conductor disposed at the second end of each resonator of the plurality of resonators, and electrically connecting the plurality of conductors to each other.
